(19) United States
(12) Patent Application Publication
(10) Pub. No.: US 2006/0216514 A1
(43) Pub. Date: Sep. 28, 2006

(54) Diamond film-forming silicon and its manufacturing method

(75) Inventors: Hiroyuki Fujimura, Tokyo (JP); Roberto Massahiro Serikawa, Kanagawa (JP); Naoki Ishikawa, Gunma (JP); Takahiro Mishima, Hyogo (JP)

Correspondence Address: HAMMER & HANF, PC, 3125 SPRINGBANK LANE, SUITE G, CHARLOTTE, NC, 28226, US

(73) Assignee: Ebara Corporation, Tokyo (JP)

(21) Appl. No.: 10/540,640

(22) PCT Filed: Dec. 24, 2003
(86) PCT No.: PCT/JP03/16552

§ 371 Date: Mar. 29, 2006

(30) Foreign Application Priority Data
Dec. 25, 2002 (JP) 2002-374788

(51) Int. Cl. C23C 16/00; B32B 9/00; B32B 13/04

(52) U.S. Cl. 428/408; 427/249.8; 428/446

(57) ABSTRACT

The present invention intends to provide a diamond-coated silicon to be used in an industrially applicable diamond electrode. A diamond-coated silicon comprising a silicon substrate having a thickness of 500 μm or less is coated at least partially with electrically conductive diamond. The silicon substrate having a thickness of 500 μm or less is manufactured by the plate-like crystal growth process, and then the silicon substrate is coated with the electrically conductive diamond by the chemical vapor deposition process to manufacture the diamond-coated silicon. The diamond-coated silicon is flexible and can be stuck to an electrically conductive support substrate, and thereby a large area electrode and a three-dimensional electrode structure can be readily obtained.

### TECHNICAL FIELD

The present invention relates to silicon coated with a film of electrically conductive diamond and a manufacturing method thereof.

### BACKGROUND ART

Diamond has the brilliance characteristic that is utilized in gems and ornaments and is known to be one of the hardest substances on the earth, and exhibits excellent physicochemical stability against frictional wear, chemical, pressure and so on. This physicochemical stability is advantageously used in many familiar products such as diamond cutter for glass, drill tool and grinder disk.

Furthermore, carbon of the diamond belongs to the same group IV of silicon. Accordingly, when carbon forms a diamond structure (sp3 crystal system), exhibits semiconductor characteristics similar to silicon, has strong interatomic binding forces, and has a large band gap such as about 5.5 eV at room temperature corresponding to the binding energy of valence electrons. Similarly to silicon, a p-type semiconductor is formed when an element of group III such as boron is used as a dopant, and an n-type semiconductor is formed when an element of group V such as nitrogen or phosphorus is used as a dopant. Accordingly, application researches of diamond electronic devices are under progress (H. Ogushi, FUTURE MATERIAL, 2, No. 10 (2002): 6-13). Although pure diamond is an excellent electrical insulator, diamond is a material whose electrical conductivity can be changed arbitrary from a degree of an insulator to that of metal by controlling the dopant amount.

Unique electrochemical characteristics of diamond are becoming evident in recent years besides the physicochemical and semiconductor characteristics. Diamond was found to exhibit wide thermodynamic window when used as an electrode in an aqueous solution. Oxygen and hydrogen are generated only under a large absolute overvoltage. The hydrogen generating potential is 0 V against the standard hydrogen electrode (SHE) and the oxygen generating potential is +1.2 V from the thermodynamic calculation. Accordingly, the width of the thermodynamic window is 1.2 V. There is a dependency to the electrolyte solution, but the thermodynamic windows are 3.2 to 3.5 V for diamond electrode, about 2.8 V for glassy carbon electrode and 1.6 to 2.2 V for platinum electrode. The wide thermodynamic windows mean that the electrode is inadequate for generating oxygen and hydrogen; however, other reactions can take place at the electrode. When diamond electrode is used for waste water treatment, for example, it is known that efficient removal of a chemical oxygen demand (COD) of the waste water can be achieved (JP-A No. 07-299467). This is attributed to the mechanism in which the OH radicals take part in the mineralization of the COD compound to carbon dioxide and to a large generation of OH radicals on the surface of the diamond electrode (JP-A No. 2000-254650). Processes of sterilizing drinking water and water for pools, cooling towers using a diamond electrode are under development due to this large generation of the OH radicals on the electrode surface.

Furthermore, the low background current (remaining current) in comparison to the other electrodes can be cited as another unique electrochemical characteristic of the diamond. The diamond, due to its low background current and to the wide thermodynamic windows, is expected to be applied to electrode for sensors of low concentrations of metals and ecological materials in aqueous solution.

Chemical vapor deposition (CVD) process is used as the process for manufacturing diamond electrode by coating the substrate with a diamond film. At present two kinds of processes are mainly used: hot-filament CVD process and microwave plasma CVD process. Both methods are processes for synthesizing artificial diamond under reduced pressure, without applying high pressure.

In the microwave plasma CVD process, plasma is generated by irradiating microwave of around 2.4 GHz to vapor of organic compounds; that become the carbon source of diamond; such as methane, acetone and the like in the range of several hundreds ppm to several percents under a hydrogen atmosphere. When the substrate, kept at a temperature in the range of 600 to 1000° C., is placed in the vicinity of generated plasma, a diamond film grows on the substrate. In order to impart electrical conductivity to the diamond film, a p-type semiconductor diamond film is grown when a boron source such as diborane or boron oxide is mingled besides methane gas under a hydrogen atmosphere. By use of the microwave plasma CVD process, mainly silicon wafer substrate is coated with the diamond film and applications such as in sensors are expected to be developed. The adhesion of the diamond film to the silicon substrate is considered to be excellent because silicon and diamond are elements that belong to the same group IV and have similar crystal structures. The diamond film closely adheres to the silicon wafer by a middle layer (interlayer) which is a very thin interlayer of silicon carbide naturally formed when the diamond film grows on silicon. The diamond film generated by the microwave plasma CVD process is known to be relatively stable and high quality (JP-A No. 10-167888).

On the other hand, in the hot-filament CVD process, diamond film grows on a substrate; disposed in the vicinity of a filament which is made of tungsten, tantalum, ruthenium, etc.; when the filament is heated to around 2000° C. under a hydrogen atmosphere containing as a carbon source few percent of at least one kind of hydrocarbons such as methane, ethane, propane, butane and unsaturated hydrocarbons, alcohols such as ethanol or ketones such as acetone. A large area of diamond film can be manufactured by disposing long filaments above this substrate. In the case that a 1-m² substrate is coated, for example, 20 filaments having a length of 1 m with intervals of 5 cm have only to be disposed above the substrate inserted in a deposition chamber. Similarly to the case of the microwave plasma CVD process, a p-type semiconductor diamond film grows when a boron source is supplied together with methane or the like. The substrate temperature in this case is maintained at about 800° C. Since the hot filament CVD process is capable of coating such large area, coating technology for metal substrates in which there is no restriction on the size is in development (JP-A 09-124395).

### DISCLOSURE OF INVENTION

(Problems that the Invention Intends to Solve)

However, silicon wafer is frequently used as the silicon substrate material for diamond electrode, and its surface area is very small. Precisely speaking, the main size of silicon wafers in the market now is 8 inch (200 mm) in diameter and even the largest one is 300 mm in diameter. Accordingly, there is a limitation in manufacturing a diamond electrode with a large surface area using silicon as the substrate material. Furthermore, when the microwave plasma CVD process is used, diamond film can be formed without difficulties on small substrates of several square centimeters; but, for the case of a large substrate such as one square meter, at present it is extremely difficult to coat the entire surface of the substrate with a diamond film. Precisely speaking, the difficulty for large coating is due to the technical difficulty in generating plasma that can cover the entire surface of such substrate of one-square meter.

Furthermore, the thickness of the silicon wafers is normally about 725 μm or more. Accordingly, when a large area electrode is tried to be prepared by connecting diamond-coated silicon wafers to an electrically conductive support substrate material with a large area, the connection is difficult because the silicon wafer has small flexibility. Additionally, the electrical conductivity of the silicon wafer becomes inevitably low due to its thickness, whereby it is difficult to use as an electrode.

Moreover, diamond having a homo-epitaxial structure can grow in the microwave plasma CVD process, if single crystal diamond is used as a substrate. However, the diamond films formed on the silicon wafers are in most cases polycrystalline diamond films.

On the other hand, as mentioned above, in the hot filament CVD process, coating technology for a metal substrate without size limitation has been developed using tantalum, niobium or tungsten as the metal substrate.

However, the crystal structures of the substrate metals are completely different from an epitaxial structure of the diamond crystal. Accordingly, a strong interlayer (middle layer) that joins the metal and the diamond is necessary in order to strongly adhere diamond to the metal substrate. For example, when a niobium metal plate will be coated with diamond, formation of a niobium carbide interlayer is necessary. However, the layer of niobium carbide is not so easily formed like in the case of silicon carbide, accordingly, before formation of the diamond film, a separate coating step of a niobium carbide layer is necessary. The coating conditions of such metal carbide are largely dependent on the pre-treatment of the substrate metal, the coating temperature and the gas composition. Operational conditions are complicated and the influences of respective operational factors on the formed metal carbide are not yet completely understood. Then, there is a problem that, depending on the state of the metal carbide layer, the quality of the coated diamond layer, in particular, the stability (durability) is largely affected. Furthermore, the crystallization process proceeds very slowly even when the film of diamond comes to be formed directly on the layer of metal carbide by means of the hot filament CVD process. Accordingly, usually it is necessary to bury diamond fine powder as seed crystals in the layer of metal carbide.

Furthermore, when a diamond electrode is manufactured using niobium as the substrate, for example, an electrically conductive support substrate with the same shape of the final electrode is prepared and directly coated thereon with a diamond film. Since the coating process is carried out at a high temperature such as 800° C. or more, there is a problem that the electrode cannot be obtained as designed because deformation by thermal effects takes place in the electrically conductive support substrate. The deformation due to the heat becomes more remarkable when the electrode has three-dimensional structure.

Still furthermore, the existing manufacturing method of diamond electrodes is basically a batch process. That means silicon wafers or metal substrates are carried into the CVD unit by lot, and pressure reduction, temperature rising, coating, temperature decreasing, pressure rising are repeated in the CVD unit, with a vast energy loss in the manufacturing method. Accordingly, these problems specially disturb the mass production of diamond electrodes and this is one of reasons why the diamond electrodes are not widely diffused.

The present invention has been made in order to overcome these problems and intends to provide an industrially applicable diamond electrode and a diamond-coated silicon that is used in the diamond electrode.

(Means for Solving the Problems)

The present inventors found that, when electrically conductive diamonds are coated on a silicon substrate with a definite thickness, the foregoing problems can be overcome, and thereby the present invention has been completed.

That is, the first aspect of the invention relates to a diamond-coated silicon comprising a silicon substrate having a thickness of 500 μm or less coated at least partially with electrically conductive diamond, wherein the silicon substrate is manufactured by the plate-like crystal growth process.

Furthermore, the second aspect of the invention relates to a manufacturing method of a diamond-coated silicon comprising coating a silicon substrate having a thickness of 500 μm or less at least partially with electrically conductive diamond by the chemical vapor deposition process.

Still furthermore, the third aspect of the invention relates to a manufacturing method of a diamond-coated silicon comprising;

a step for manufacturing a silicon substrate having a thickness of 500 μm or less by the plate-like crystal growth process; and

a step for coating the manufactured silicon substrate at least partially with electrically conductive diamond by chemical vapor deposition process.

### BRIEF DESCRIPTION OF THE DRAWINGS

FIG. 1 is a diagram showing schematically a manufacturing process of a diamond-coated silicon and an electrode according to the present invention.

FIG. 2 is a diagram showing a manufacturing process of the diamond-coated silicon, which uses the microwave plasma CVD process.

FIG. 3 is a diagram showing a detail of a rubber damper portion.

FIG. 4 is a diagram showing a manufacturing process of the diamond-coated silicon, which uses the microwave plasma CVD process.

FIG. 5 is a diagram showing a manufacturing process of the diamond-coated silicon, which uses the hot filament CVD process.

FIG. 6 is a diagram showing a temperature variation in the respective steps of the hot filament CVD process.

### BEST MODE FOR CARRYING OUT THE INVENTION

The plate-like crystal growth process used in the present invention means a process to obtain a plate-like silicon substrate and is not restricted to a particular one as far as it can obtain a silicon substrate having a thickness of 500 μm or less. As specific examples of the plate-like crystal growth processes, the EFG process (Edge-defined Film-fed Growth process), the string ribbon process or the dendritic web process can be preferably cited, and among these the dendritic web process can be cited as a more preferable example. The EFG process is a method to obtain silicon substrate; in which melt silicon is forced to rise by the capillary effects through a slit of a die; that is a mold to feed the melt silicon and to define the crystal shape; followed by pulling up of solidified silicon by bringing into contact with seed crystals. The string ribbon process is another method to obtain the silicon substrate, in which a film supported by the surface tension between several strings are solidified and pulled up from the melt silicon in a vertical direction. The dendritic web process is also another method for producing silicon substrate; in which a thin film (web) supported by the surface tension between several dendrites are pulled out and solidified from the melt silicon. The dendrites are extended from the seed crystals that are brought into direct contact with the melt silicon, without using dies. (JP-A Nos. 63-144187 and 2000-319088).

Silicon substrate having a large surface area can be easily obtained from these plate-like crystal growth processes and the diamond-coated silicon according to the present invention has particular advantage when used for large area electrode in industrial application.

There is no particular lower limit for the thickness of the silicon substrate used in the invention. However, from a viewpoint of handling convenience, thickness of 0.1 μm or more is preferable. That is, the thickness of the silicon substrate to be used in the invention is preferably in the range of 0.1 to 500 μm, more preferably in the range of 10 to 300 μm, and still more preferably in the range of 50 to 200 μm. When the thickness exceeds 500 μm, the electrical resistance becomes higher, resulting in disadvantages when used as an electrode. Furthermore, when the thickness exceeds 500 μm, due to the decrease in flexibility, there are problems of fragility increase and problems related to being readily cracked due to the difficulty in tolerating the thermal expansion by the heat generated when used at high current density.

Furthermore, the silicon substrate used in the invention may be any one of single crystal, polycrystal or amorphous; however, from the viewpoints of facility in diamond film coating and better adhesiveness, a single crystal is preferably used.

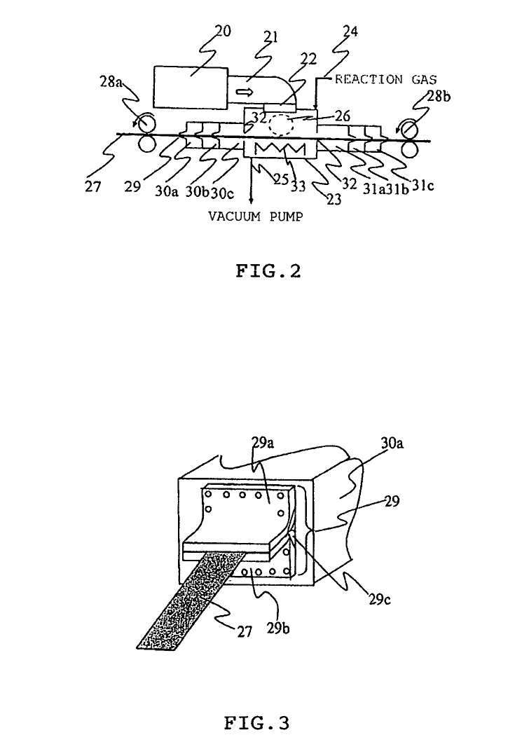

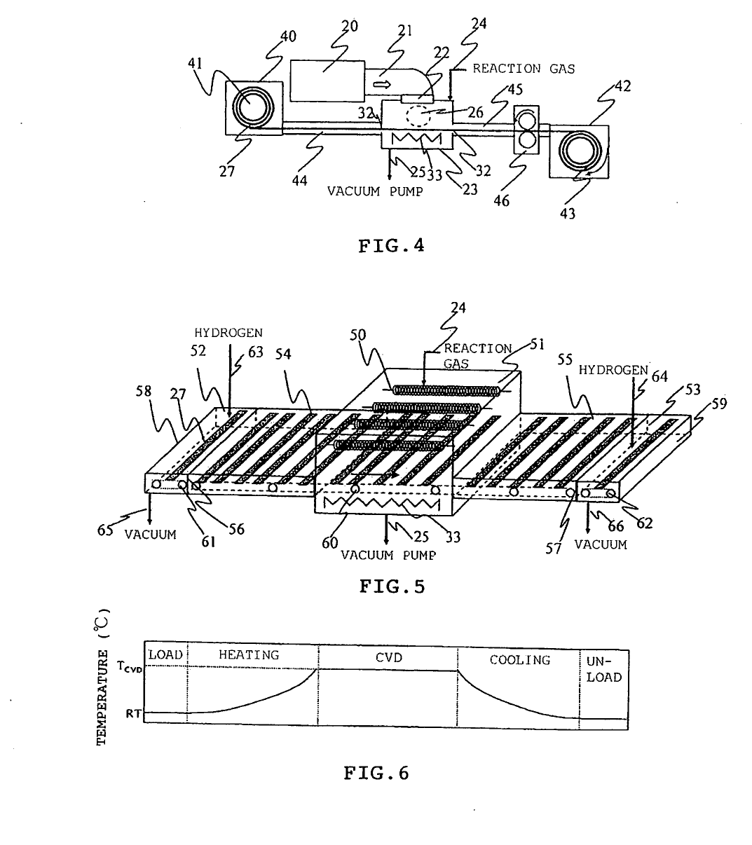

When longer diamond-coated silicon is manufactured, embodiments shown in FIGS. 2 and 4 described below can be used. Furthermore, when small diamond-coated silicon are necessary such as for use in sensors, it can be obtained by cutting diamond-coated silicon with a diamond cutter into an arbitrary small size.

The diamond-coated silicon according to the present invention can be manufactured by coating a silicon substrate, having a thickness of 500 μm or less, at least partially with electrically conductive diamond by means of a CVD process. Hereunder, a manufacturing method of a diamond-coated silicon according to the present invention will be described with reference to the drawings.

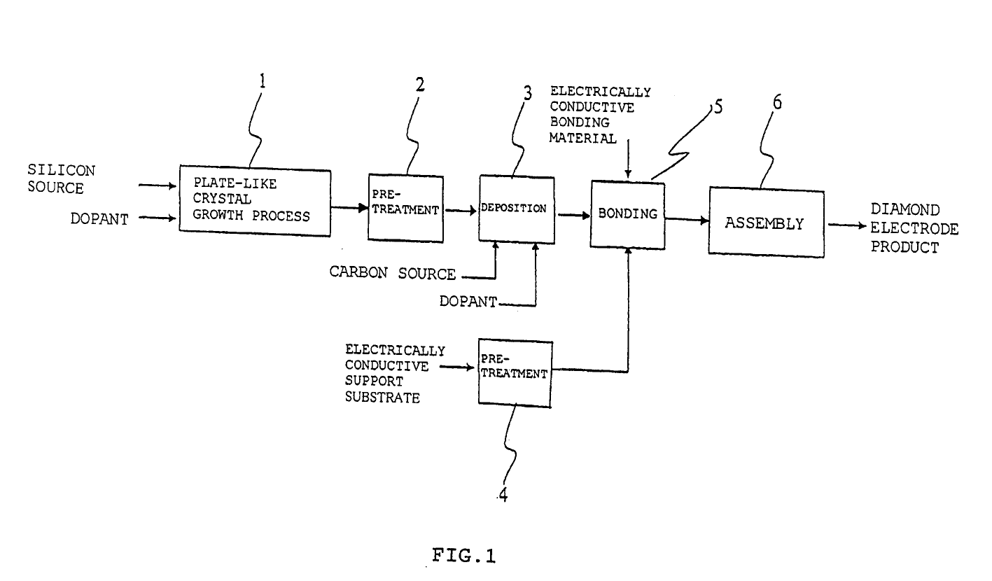

FIG. 1 shows an example of an embodiment of a manufacturing method according to the present invention. In this embodiment, the manufacturing method includes; manufacturing a silicon substrate having a thickness of 500 μm or less according to the plate-like crystal growth process step 1; pre-treating step 2 prior to a CVD diamond coating; and a diamond coating step 3. Thereafter, when an electrode is manufactured, pre-treating step 4 of the electrically conductive support substrate; bonding step 5 of the diamond-coated silicon and the electrically conductive support substrate with an electrically conductive bonder; and assembling step 6 of the electrode are carried out.

A silicon raw material and a dopant are introduced and a silicon substrate having a thickness of 500 μm or less is manufactured according to the plate-like crystal growth process 1 (step (a)). When a p-type silicon substrate is manufactured, a boron source, a gallium source or an indium source is preferably used as the dopant. When an n-type silicon substrate is manufactured, a phosphorus source, an antimony source or an arsenic source can be preferably used as the dopant. The dopant is preferably added in the manner that the electrical resistance (specific resistance) of the silicon substrate becomes 10 Ωcm or less, preferably 50 mΩcm or less, and more preferably 15 mΩcm or less. The silicon substrate may be doped by means of the ion injection method after it is pulled up from the melting furnace. In this case, there is no need of introducing the dopant in the melting furnace.

The width of the silicon substrate is normally in the range of 1 to 300 mm, preferably in the range of 5 to 200 mm, and more preferably in the range of 10 to 150 mm. The coating with diamond may become difficult in some cases, when the width is less than 1 mm, because of the poor mechanical strength. Uniform silicon substrate may become difficult to be obtained in some cases when the width exceeds 300 mm. Since the length of the silicon substrate manufactured here is endless, the silicon substrate may be continuously supplied by conveyer to the pre-treating step 2 prior to the diamond coating, and further at least a part thereof may be supplied to the film coating step (step (e)) in which the silicon substrate is coated with electrically conductive diamond by the CVD process. In this case, the step (a) and the step (e) are successively carried out.

Since the extracting speed of the silicon substrate is constant, depending on the thickness of diamond to be coated, the coating speed cannot follow this extracting speed in some cases. That is, the coating speed is normally about 0.1 to 5 μm/h when the diamond film is coated in the CVD process, and therefore the retention time in a CVD chamber becomes necessarily to be approximately 3 hr when a 3 μm thick diamond film is coated at 1 μm/h, for example. In such a case, the silicon substrate is preferably cut into a prescribed length by use of a diamond cutter or the like immediately after taking out from the melting furnace. The cutting length here can be determined according to a final shape of the electrode, applications, or configuration of the CVD device described below. The silicon substrate cut into a prescribed length is sent to the pre-treating step 2 in a batch-wise manner.

The silicon substrate immediately after extracted from the melting furnace is still at a high temperature; accordingly, the silicone substrate is preferably cooled once at a temperature rate of 50° C./h or less. The silicon substrate cooled to near room temperature is transferred to the pre-treating step 2, and metal impurities and silicon oxide layers adhered to the vicinity of the surface of the silicon substrate are cleaned and etched. An aqueous solution of hydrochloric acid is normally used to remove the metal impurities and an aqueous solution of hydrofluoric acid is normally used to remove the silicon oxide layers. Because the silicon oxide layers naturally forms in few hours after the etching, this removal of the silicon oxide is preferably carried out immediately before transferring to the diamond coating step 3.

In the present invention, the diamond coating step can be carried out either continuously or in a batch-wise manner. When it is continuously carried out, a microwave plasma CVD process can be preferably used, and when the batch process is adopted, a hot filament CVD process can be preferably used. However, the present invention is not limited to these combinations.

FIGS. 2, 4 and 5 show some examples of silicon substrate coated with a diamond film. FIGS. 2, 4 and 5 show suitable examples for coating the substrate, with a diamond film, having a length of 1 to 20 m, 20 to 300 m, and 2 m or less, respectively. These dimensions are only approximate values and there is not necessity to be strict followed.

FIG. 2 shows a suitable example for coating silicon substrate having length of 1 to 20 m with a diamond film in the microwave plasma CVD process. The microwave generation portion includes a microwave generator 20, a microwave waveguide 21, and a window 22 for the penetration of the microwave. The frequency of the microwave generator 20 may be an ordinarily used 2.45 GHz or higher. The window 22 is not particularly restricted to sapphire or quartz, as far as it can transmit the microwave and sealing the pressure. A plasma ball 26 is generated and the diamond film coating proceeds on the surface of silicon substrate 27; when the microwave is irradiated; after introducing a reaction gas 24 composed of hydrogen, a carbon source such as methane and a dopant source; in the CVD chamber 23 at a prescribed temperature and pressure.

The temperature of the silicon substrate at the time of coating with the diamond film is preferably controlled to a prescribed temperature in the range of 600 to 1000° C. In order to control the temperature of the silicon substrate, a heater 33 may be disposed.

For the purpose of maintaining the CVD chamber 23 at a constant pressure during the diamond film coating; or for the purpose of device cleaning-up by evacuating at high vacuum condition during the start-up; the CVD chamber is connected to a vacuum pump through a path 25. In addition to the microwave generation portion, the CVD device is preferably provided in separate with vacuum chambers 30 and 31, where the silicon substrate 27 is loaded and unloaded. The vacuum chambers 30 and 31 are respectively divided in three partitions 30a, 30b, 30c and 31a, 31b, 31c with different pressure and temperature. The partitions 30a, 30b, 31b and 31c are respectively provided with a vacuum pump and a pressure controller with different set-up. The chambers 30 and 31 are partitioned with the CVD chamber 23 and opening 32, and the pressure of partitions 30c and 31a is kept to the same as that of the CVD chamber 23. The pressures of the partitions 30b and 31b are maintained at a pressure higher than that of the CVD chamber 23. For example, when the CVD chamber 23 is operated at 10 Torr, the pressures of the partitions 30b and 31b are maintained at 100 Torr. At this time, the pressures of the partitions 30a and 31c are set at 400 Torr, for example. Thus, a system in which the ambient pressure is gradually reduced, through the partitions, to the pressure of CVD chamber 23 is preferably provided. This feature is for avoiding the air leak into the CVD chamber 23, accompanying the silicon substrate. The pressure control by means of any one of the partitions 30a, 30b and 30c constitutes the step (d) according to the present invention in which the pressure is controlled at least once, and the pressure control by means of any one of the partitions 31a, 31b and 31c constitutes the step (f) according to the present invention in which the pressure is controlled at least once.

Furthermore, the partitions are provided with a rubber damper 29 to avoid the entrance of air. FIG. 3 shows a detail of rubber damper portion. The rubber damper 29 is constructed from two rubber plates 29a and 29b which are disposed upper and lower part, and they are connected to the wall surface of partition 30a, and further fixed with screws. The upper and lower rubber plates 29a and 29b have an overlapped portion and the silicon substrate 27 is hold between the overlapped portions. Furthermore, there will be a gap at the place in which the rubber plates 29a or 29b bends 90°. This gap is sealed with a tapper 29c. Since the rubber damper 29 has a reduced pressure in one side, it will closely contact the silicon substrate 27 due to the pressure gradient and will works as a system for avoiding the entrance of air. Various kinds of rubber materials such as natural rubbers and silicone rubbers can be used as a material of the damper 29, and among then fluorinated rubbers which are excellent in the heat resistance and the chemical resistance can be preferably used. This air-sealing system that employs the rubber damper 29 can be configured only when a silicon substrate having thickness of 500 μm or less is used. Such a sealing system cannot be put in practice with the existing circular silicon wafer having roughly 1 mm in thickness and 300 mm in diameter. The lengths of the partitions 30c and 31a are appropriately determined depending on the loading speed of the silicon substrate and normally they are about 50 cm. When the lengths of the partitions 30c and 31a are extremely short, the sealing ability may deteriorate when the temperature becomes 150° C. or more even using these rubber materials. In the example according to this embodiment, the system for temperature control of these partitions is not provided, but a temperature control system may be provided when a precise temperature control is required.

Because the thickness of a silicon substrate to be introduced is such thin as 500 μm or less, the heights of the vacuum chambers 30 and 31 can be set low, for example, to 1 mm or less, and thereby a compact device structure can be realized. The opening 32 has a height enough to blocking the microwave and allowing the insertion of silicon substrate and may be provided with a gate structure that varies according with the thickness of the silicon substrate to be coated with the diamond film. The width of the opening portion 32 can also be appropriately adjusted according to the silicon substrate to be coated and is normally 300 mm or less. The leaking of the microwave, to the ambient air or to the vacuum chambers 30 and 31, is avoided because this opening is relatively wide in the width but low in the height. This opening portion 32 and the CVD chamber 23 are preferably made of metallic material to block the microwaves. Furthermore, since the silicon substrate is flexible, a metal mesh or a slatted drainboard is preferably disposed above the heater 33 of the CVD chamber 23.

The feed speed of the silicon substrate through the CVD chamber 23 is controlled with the rotating units 28 disposed before and after the CVD chamber 23. At the time of start of the film coating, the rotating unit 28a on the inlet side pushes the tip of silicon substrate 27 to below the plasma ball 26. Once the diamond-coated silicon reaches the rotating unit 28b on the outlet side, the chamber feed speed may be controlled by the rotating unit 28b. The retention time of the silicon substrate 27 in the CVD chamber 23 can be varied with the rotating units 28, and thereby the thickness of the coated diamond film can be controlled. The feed speed of the silicon substrate 27 may be 1 to 500 mm/h, for example. As a matter of course, the feed speed can be raised faster if a CVD technology that can grow a diamond film at a higher speed is developed in future as a result of the advance of technology. The coating with the diamond film starts only after the silicon substrate 27 reaches below the plasma ball 26 in the CVD chamber 23. Accordingly, the silicon substrate 27 may be inserted at a higher speed until the silicon substrate 27 reaches below the plasma ball. On the wall surface of the CVD chamber 23, a viewport window made of quartz or the like can be further disposed to confirm the arrival to the plasma ball 26. In this case, a microwave shield structure which is made of a metal mesh or printed mesh-like metal like used in a microwave oven is preferably provided in the window.

Since the microwave plasma CVD process has difficulty, in particular, in generating and controling large area plasma, the width of the silicon substrate to be used in the embodiment is normally 300 mm or less, preferably 200 mm or less and more preferably 150 mm or less.

The present invention; allows to coat easily and continuously diamond film, with microwave plasma CVD process, by using silicon substrate having a thickness of 500 μm or less as the film coating substrate; thereby contributes to the mass-production of electrodes that will be described later.

FIG. 4 shows an embodiment preferable for coating a silicon substrate having a length of 20 m or more with a diamond film. In FIG. 4, the CVD chamber 23 and a microwave generation portion are the same as that in FIG. 2. However, loading and unloading mechanisms of the silicon substrate are different from the above. After the silicon substrate 27 is manufactured by the plate-like crystal growth process, the silicon substrate 27 is wound around the drum 41 by a step (b) for winding the silicon substrate. The diameter of the drum 41 is normally 50 mm or more, preferably 300 mm or more, and more preferably 600 mm or more. When the diameter is less than 50 mm, cracks can easily appear, in particular at the single crystal silicon, due to the bending. Furthermore, the diamond-coated silicon is recovered as a bobbin wound around the drum 43 and the drum 43 has also a preferable diameter of 50 mm or more. Still furthermore, the thickness of the coated diamond film is normally 20 μm or less, preferably 10 μm or less, and more preferably 5 μm or less. Since the diamond-coated silicon is recovered around the drum 42, cracks may easily appear at the diamond coated portion when the thickness of the diamond film is 20 μm or more. Furthermore, the drum 42 is preferably installed, in such a way that the face with the diamond film becomes the outward face. This feature is required, because the thermal expansion coefficient of diamond is smaller than that of the silicon. The silicon substrate is in an elongated state at the diamond coating CVD chamber where the temperature is in the range of 600 to 1000° C. When cooled to the vicinity of room temperature, the diamond film layer is compressed due to shrinking of the silicon substrate. The diamond film layer will be further compressed, if the silicon substrate with the face of diamond film is wound inward in the drum box 42, causing additional instability in the diamond layer.

The silicon substrate 27 is loaded or unloaded in batch-wise. However, once it is set, long silicon substrate can be continuously coated and it plays an important role to the mass-production of electrodes described below. The drum boxes 40 and 42 and paths 44 and 45 basically have the same pressure as that of the CVD chamber 23 and have structures capable of isolating pressure from ambient air. During the start-up of the film coating, the drum boxes 40 and 42 are opened, the silicon substrate 27 in the bobbin format of drum 41 is set, and the tip of the silicon substrate is drawn to the drum 43 to allow the drum to start winding. Once the silicon substrate between the area below the plasma ball 26 and the drum 43 will be not coated and wasted at this time, a dummy made of another material may be connected to the tip of the silicon substrate 27. After the drum 41 is set, for the removal of the air, the entire system is evacuated with a vacuum pump connected through a path 25 to 0.1 Torr or less. Then, the reaction gas 24 is introduced into the CVD chamber 23, and the gas flow rate and the vacuum pump are adjusted, and under prescribed decompression, the coating process are initiated by operating the microwave generator. The feed speed of the silicon substrate 27 in the CVD chamber 23 is preferably controlled with the rotating unit 46. The drum 43 is rotated under a torque enough to wind the silicon substrate without slack and the retention time is controlled by the rotation speed of the rotating unit 46. The feed speed cannot be controlled constant by the constant rotation speed of the drum 43, since the winding diameter increases as the diamond-coated silicon is wound. The feed speed can be controlled depending on the thickness of the diamond film to be coated and is normally in the range of 1 to 500 mm/h. As a matter of course, the feed speed can be raised faster if a CVD technology that can grow a diamond film at a higher speed is developed in future as a result of the advance of technology. The step for loading the silicon substrate 27 into the CVD with the rotating unit 46 constitutes the step (c) for supplying a wound silicon substrate to the CVD unit according to the present invention. Furthermore, the step for winding the diamond-coated silicon around the drum 43 constitutes the step (g) for winding the diamond-coated silicon according to the present invention.

The present invention; as obvious from examples shown in FIGS. 2 and 4, allows to coat continually diamond film even using the microwave plasma CVD process that usually are not appropriate to coat large area; considerably contributes to the mass-production of electrodes described later.

In the following, an example of an embodiment according to the present invention in which the hot filament CVD process is employed is shown in FIG. 5. This is a coating process and device suitable for the case that the silicon substrate of 2 m or less in length. The coating device includes a CVD chamber 51, a load chamber 52, an unload chamber 53, a heating chamber 54 and a cooling chamber 55. The load and unload chambers are constructed to completely sealing pressure by means of gates 56 and 57. Furthermore, the load chamber 52 and the unload chamber 55, respectively, have a gate 58 for loading the silicon substrate 27 and a gate 59 for unloading the diamond-coated silicon. Metal conveyers 60, 61 and 62 for transporting the silicon substrate 27 are disposed below the respective chambers. Tungsten filaments 50 for CVD coating are disposed; in the upper portion of the CVD chamber 51; in right angle to the longitudinal direction of the silicon substrate 27. The tungsten filaments do not need to be necessarily disposed in right angle but they are preferable in a right angle position. That means, when the silicon substrate 27 has length of 1 m or more, filaments with length longer than 1 m will have to be equipped; for disposing in the same direction. During the diamond film coating, the filament temperature becomes such as high as about 2000° C. with slacking the filaments themselves. Accordingly, the filaments are preferably disposed in right angle to use as short as filament length. The CVD chamber 51 is provided with a pipe for introducing the reaction gas 24 and a path 25 for evacuation. The load chamber 52 and unload chamber 53 are provided with hydrogen introduction lines 63 and 64 and further with evacuation lines 65 and 66. Furthermore, the CVD chamber 51 is provided with a heater 33 for controlling the temperature of the silicon substrate when coated with the diamond film, and the temperature of the silicon substrate is controlled in the range of 600 to 1000° C. during diamond film coating.

The heating chamber 54 and the cooling chamber 55, as shown in FIG. 6, have a structure in which the temperature may not rapidly rise or decrease between the silicon substrate temperature in the CVD chamber 51 (T_{CVD}) and room temperature (RT). This is for avoiding the silicon substrate 27 being damaged due to the thermal shock or the like. Furthermore, during the temperature decrease of the diamond-coated silicon, it is necessary to alleviate the stress generated due to the difference in the thermal expansion coefficients between the diamond layer and the silicon layer. The temperature decreasing or rising rate is preferably set so that the temperature change of the silicon substrate is 50° C./h or less. In the heating chamber 54 and the cooling chamber 55, such temperature distribution can be naturally achieved due to the heat irradiation and natural convection in the CVD chamber 51. However, when a more precise temperature distribution is required, an auxiliary heater or an indirect cooling unit may be provided at a lower portion of the heating chamber 54 and/or cooling chamber 55.

In the next, the film coating operation of the silicon substrate in this embodiment will be described. In a steady state operation, hydrogen gas, few % of methane, and few hundreds to few thousands ppm of a dopant source are maintained inside of the CVD chamber 51, heating chamber 54 and cooling chamber 55 under the pressure range of 0.5 to 100 Torr. In the CVD chamber 51, the diamond film is coated with temperatures of the filament 50 kept at the vicinity of 2000° C. and the substrate temperature kept at 800° C. The gate 56 is closed and the gate 57 is opened. When the silicon substrate 27 is introduced, the inside of the load chamber 52 is evacuated (to 0.1 Torr) and the reaction gas is removed from the load chamber 52 at first. Subsequently, air is introduced in the load chamber 52; through a path (not shown in the drawing) different from the hydrogen line; until achieving atmospheric pressure. The gate 58 is opened only after the atmospheric pressure is achieved, and then the silicon substrate 27 is introduced in the load chamber 52. In FIG. 5 shows only one silicon substrate being loaded; but several silicon substrates can be loaded in once time. After the silicon substrate 27 is introduced, the gate 58 is closed, followed by vacuum and removal of the air inside the load chamber 52. Then, hydrogen is introduced through the line 63 until the pressure became same as that of the CVD chamber 51, thus the film coating became in stand by condition. In the CVD chamber 51, the silicon substrates 27 are successively subjected to the coating, and the diamond-coated silicon are transferred to the connected cooling chamber 55 and slowly cooled to a temperature in the vicinity of room temperature. Since the gate 57 is opened, unload operation begins when the cooled diamond-coated silicon comes closer to the unload chamber 53. When the diamond-coated silicon comes near the unload chamber 53, the conveyer 60 is operated at first so that the diamond-coated silicon comes completely inside of the unload chamber 53. The approach of the diamond-coated silicon to the unload chamber 53 can be detected by means of a positional sensor such as various kinds of commercially available laser sensors. When the diamond-coated silicon is completely introduced into the unload chamber 53, the gate 57 is closed, followed by evacuating the reaction gas through the line 66. Subsequently, air is introduced into the unload chamber 53 through a path (not shown in the drawing) different from the hydrogen line, the gate 59 is opened and the diamond-coated silicon is unloaded. When the gate 57 is closed, at the beginning of the unloading operation; the loading operation of the silicon substrate 27 that was kept in standby condition in the load chamber 52 is carried out. In the loading operation, the gate 56 is opened and the feed operation of the conveyer 61 is carried out. Since the conveyer 60 of the heating chamber 54 always runs at a constant speed; it takes some time to the silicon substrate 27 be completely moved to the heating chamber. It is preferable to detect the moment in which the silicon substrate 27 has completely entered into the heating chamber using positional sensor such as a laser sensor. The gate 56 is closed after the silicon substrate has completely entered into the heating chamber 54. After finishing the removal of diamond-coated silicon from the unload chamber 53; the gate 59 is closed, and the air in the unload chamber 53 is evacuated. Subsequently, hydrogen gas is introduced through the line 64 and thereby the pressure becomes the same as that of the CVD chamber 51. After the pressure is confirmed to be the same, the gate 57 is opened. By repeating these operations, the diamond film is semi-continuously coated by means of the hot filament CVD process. In the example according to this embodiment, the hydrogen gas is filled during the loading and unloading operations in order to equalize the pressure; but also the reaction gas may be filled in place of the hydrogen gas. However, the soot tends to be generated when the reaction gas, containing the carbon source, is submitted to a medium temperature in the range of 300 to 600° C. Accordingly, the hydrogen gas is preferably used in the loading and unloading operations. The dimensions of the load and unload chambers can be build smaller in the height; as far as the silicon substrate 27 can be carried on the conveyer. Accordingly, the volume to be evacuated and filled with the hydrogen gas can be made smaller, and therefore compact load and unload chambers can be designed. That means, there is no need for evacuating the whole CVD chamber such as in the existing conventional hot filament CVD devices. Furthermore, according to this embodiment, the temperatures of the filaments of the CVD and the CVD chamber are always kept constant. Different from the conventional hot filament CVD devices and methods, there is no need for repeating rising and decreasing of temperature and vacuum operation for each substrate. As a result, the film coating cost such as the electricity is considerably reduced and the life time of filament are prolonged in addition.

### ADVANTAGE OF THE INVENTION

According to the present invention, a diamond-coated silicon used in a diamond electrode can be readily manufactured. Furthermore, when the diamond-coated silicon according to the present invention is used, a large area electrode and a three-dimensional electrode structure can be obtained.

1. A diamond-coated silicon comprising a silicon substrate having a thickness of 500 μm or less coated at least partially with electrically conductive diamond, wherein the silicon substrate is manufactured by the plate-like crystal growth process.

2. The diamond-coated silicon according to claim 1, wherein the plate-like crystal growth process is at least one selected from the EFG process, the string ribbon process and the dendritic web process.

3. The diamond-coated silicon according to claim 1, wherein the silicon substrate is single crystalline, polycrystalline or amorphous.

4. The diamond-coated silicon according to claim 1, wherein the silicon substrate is coated with electrically conductive diamond by the chemical vapor deposition process.

5. A manufacturing method of a diamond-coated silicon comprising coating a silicon substrate having a thickness of 500 μm or less at least partially with electrically conductive diamond by a chemical vapor deposition process.

6. A manufacturing method of a diamond-coated silicon comprising the steps of;
(a) manufacturing a silicon substrate having a thickness of 500 μm or less by a plate-like crystal growth process; and
(e) coating the manufactured silicon substrate at least partially with electrically conductive diamond by chemical vapor deposition process.

7. The manufacturing method of a diamond-coated silicon according to claim 6, wherein the plate-like crystal growth process is selected from the group consisting of: an EFG process, a string ribbon process and a dendritic web process.

8. The manufacturing method of a diamond-coated silicon according to claim 6, wherein the step (a) and the step (e) are successively carried out.

9. The manufacturing method of a diamond-coated silicon according to claim 6, further comprising, between the step (a) and the step (e),
(d) a step for controlling a pressure at least once.

10. The manufacturing method of a diamond-coated silicon according to claim 6, further comprising, after the step (e),
(f) a step for controlling a pressure at least once.

11. The manufacturing method of a diamond-coated silicon according to claim 6, further comprising, between the step (a) and the step (e),
(b) a step for winding the silicon substrate; and
(c) a step for supplying the wound silicon substrate to a chemical vapor deposition device.

12. The manufacturing method of a diamond-coated silicon according to claim 6, further comprising, after the step (e),
(g) a step for winding a diamond-coated silicon.

13. The diamond-coated silicon according to claim 2, wherein the silicon substrate is single crystalline, polycrystalline or amorphous.

14. The diamond-coated silicon according to claim 2, wherein the silicon substrate is coated with electrically conductive diamond by the chemical vapor deposition process.

15. The diamond-coated silicon according to claim 3, wherein the silicon substrate is coated with electrically conductive diamond by the chemical vapor deposition process.

16. The manufacturing method of a diamond-coated silicon according to claim 7, wherein the step (a) and the step (e) are successively carried out.

17. The manufacturing method of a diamond-coated silicon according to claim 7, further comprising, between the step (a) and the step (e):
(d) a step for controlling a pressure at least once.

18. The manufacturing method of a diamond-coated silicon according to claim 8, further comprising, between the step (a) and the step (e):
(d) a step for controlling a pressure at least once.

19. The manufacturing method of a diamond-coated silicon according to claim 7, further comprising, after the step (e):
(f) a step for controlling a pressure at least once.

20. The manufacturing method of a diamond-coated silicon according to claim 8, further comprising, after the step (e):
(f) a step for controlling a pressure at least once.

21. The manufacturing method of a diamond-coated silicon according to claim 9, further comprising, after the step (e):
(f) a step for controlling a pressure at least once.

22. The manufacturing method of a diamond-coated silicon according to claim 7, further comprising, between the step (a) and the step (e):
(b) a step for winding the silicon substrate; and
(c) a step for supplying the wound silicon substrate to a chemical vapor deposition device.

23. The manufacturing method of a diamond-coated silicon according to claim 8, further comprising, between the step (a) and the step (e):
(b) a step for winding the silicon substrate; and
(c) a step for supplying the wound silicon substrate to a chemical vapor deposition device.

24. The manufacturing method of a diamond-coated silicon according to claim 9, further comprising, between the step (d) and the step (e):
(b) a step for winding the silicon substrate; and
(c) a step for supplying the wound silicon substrate to a chemical vapor deposition device.

25. The manufacturing method of a diamond-coated silicon according to claim 10, further comprising, between the step (a) and the step (e):
(b) a step for winding the silicon substrate; and
(c) a step for supplying the wound silicon substrate to a chemical vapor deposition device.

26. The manufacturing method of a diamond-coated silicon according to claim 7, further comprising, after the step (e):
(g) a step for winding a diamond-coated silicon.

27. The manufacturing method of a diamond-coated silicon according to claim 8, further comprising, after the step (e):
(g) a step for winding a diamond-coated silicon.

28. The manufacturing method of a diamond-coated silicon according to claim 9, further comprising, after the step (e):
(g) a step for winding a diamond-coated silicon.

29. The manufacturing method of a diamond-coated silicon according to claim 10, further comprising, after the step (f):
(g) a step for winding a diamond-coated silicon.

30. The manufacturing method of a diamond-coated silicon according to claim 11, further comprising, after the step (e):
(g) a step for winding a diamond-coated silicon.
